(19) United States
(12) Patent Application Publication
(10) Pub. No.: US 2025/0190660 A1
(43) Pub. Date: Jun. 12, 2025

(54) SYSTEM AND METHOD FOR DEPTH MATCHING OF WELL LOG DATA

(71) Applicant: CGG SERVICES SAS, Massy Cedex (FR)

(72) Inventors: Nguyen LE, Crawley (GB); Henning HOEBER, Keltneyburn (GB); David O'CONNOR, Colwyn Bay (GB)

(21) Appl. No.: 18/961,710

(22) Filed: Nov. 27, 2024

Related U.S. Application Data
(60) Provisional application No. 63/607,157, filed on Dec. 7, 2023.

(51) Int. Cl. G06F 30/28

(52) U.S. Cl. CPC G06F 30/28

(57) ABSTRACT

A method for depth matching well log data associated with a subsurface includes receiving recorded well log data, dividing the recorded well log data into a primary log and a secondary log, wherein the primary log is related to a first measured parameter and the secondary log is related to a second measured parameter, which is different from the first measured parameter, calculating depth shifts for the primary log and performing depth matching of the primary log, based on the calculated depth shifts, to obtain a depth matched primary log, applying the same depth shifts to the second log, and generating a map of geological features of the subsurface based on the depth matched primary and secondary logs.

### BACKGROUND OF THE INVENTION

### Technical Field

Embodiments of the subject matter disclosed herein generally relate to a system and method for matching depths of well log data, and more particularly, to a method and system that automatically aligns depths of well log data associated with a well (this process is called “compositing” in the field).

### Discussion of the Background

When a well (see well 100 in FIG. 1) is drilled for exploring the existence of desired resources 102 (such as oil and gas or other minerals) in a subsurface 104, rock samples such as cuttings 110 and rock cores 120 are acquired from the well and analyzed to determine the physical and chemical nature of a geological formation 106 extending along the well 100. The rock sample analysis yields information such as mineralogy, texture, petrophysical properties, elastic properties, fluid content, geologic age, and potential oil and gas productivity of reservoir rocks at the location from which the samples are acquired. Various methods and tools for rock sample analysis enable hydrocarbon reservoir characterization, drilling optimization, and production management.

The cuttings 110 are sand-like particles produced by a rotary bit (not shown) as the well 100 is drilled into the subsurface 104. The rock cores 120 are small portions of a rock formation extracted from an existing well. Each of these samples is associated with a location D (e.g., depth or range of depths) along the well 100.

As illustrated in FIG. 1, rock samples (cuttings 110 or core plugs 120) may be collected along the well at regular or variable intervals, e.g., between 3 and 20 m, but gaps larger than 20 m may occur due to well drilling-related limitations. The rock samples are investigated (for example, using a portable rock analysis lab such as RoqSCAN™), and a log (i.e., a series of pairs of property values and corresponding location/depths) with sampling intervals (d₁, d₂, d₃, etc.) is generated for each mineralogical, textural, petrophysical and elastic property that has been obtained from the rock analysis. A well log may include a series of much more frequent sampling measurements, for example, at 20 cm along the well.

Logging tools performing these measurements may be a string of one or more instruments and sensors that are lowered into the well (e.g., the sensors may be part of the drill). Logging tools may measure the natural gamma ray, electrical, acoustic, stimulated radioactive responses, electromagnetic, nuclear magnetic resonance, pressure and other properties of the rocks and the fluids they contain. Other measurement sensors and devices may be used independently. The well logs may include values obtained by scanning one or more of density, porosity, resistivity, gamma-ray response, etc., along the well.

The well logs are used by the well operator to interpret the properties of the subsurface 104, i.e., to essentially distinguish between the resource 102 and a region where there are no resources of interest. However, a problem with the interpretation of a well log is that the acquired data is not well aligned along the depth of the well. This happens because the well log is not acquired in one step, but multiple steps are required, and each step may misread the actual depth of the well where the rock samples are acquired. For example, after drilling a first portion of the well, the drill may be taken out and a wireline logging is performed for the first portion during a first step. Next, the wireline is removed and the drill is lowered into the well and the drilling operation continues for a second portion of the well. At the end of drilling the second portion, the drill is again removed from the well and the wireline logging is lowered into the well and the measurements are repeated. During this second step, log data of the first portion may be reacquired and log data for the second portion is freshly acquired. Thus, the data acquired during the second step may be depth misaligned with the data from the first step (for the same portion of the well). In other words, raw well log data usually comes as several pieces acquired at different depth intervals called “runs.” Although multiple depth corrections are applied by the logging companies, the depth recordings of different runs or even in the same run can still be misaligned.

The performance of the data logging during different acquisition phases sometimes results in the collection of different data over the same depth (e.g., the first portion noted above). This process results in having plural log runs for the same portion of the well. A “log run” is defined in this document as being a space interval in which well log data is acquired continuously (e.g., log runs d1 to d3 in FIG. 1). For example, the log run may correspond to a distance of about 100 to 500 m. Other values for the log run may be used. However, these log runs are most of the time misaligned because various conditions are encountered in the field when recording the data during the different phase of the well drilling. These depth misalignments in the log data create accuracy problems in the processing stage, when the data is analyzed to predict the location of the resources.

Different groups have tried using various methods for aligning the well data as the validity of any interpretation technique or machine learning model applied on well log data relies on the assumption that the data are depth aligned. Depth matching is often performed manually by petrophysicists by looking at each log pair and moving one to match the another. However, this approach is very slow and subjective.

There have been several attempts to automate depth matching as summarized below. Some of these attempts include a search of maxima of correlograms calculated between a window centered on each sample of a “new curve” and a window of a “base curve,” as discussed in [1]. The authors in [2] have tried the minimization of the sum of curve distortion and discarded correlation coefficients, solved by dynamic programming. The authors in [3] have used multiclass classification by a feedforward neural network to predict the index of a point in the desynchronized window that corresponds to the center of the reference window of gamma ray logs. The authors in [4, 5] have applied a regression by one-dimensional convolutional neural networks with different fusion strategies to predict amounts of shift to match wireline and logging-while-drilling data.

However, all these attempts still suffer of some degree of depth misalignment. Thus, there is a need for a new system and method that are capable of better aligning the various logging data acquired for a given well.

### SUMMARY OF THE INVENTION

According to an embodiment, there is a method for depth matching well log data associated with a subsurface, and the method includes receiving recorded well log data, dividing the recorded well log data into a primary log and a secondary log, where the primary log is related to a first measured parameter and the secondary log is related to a second measured parameter, which is different from the first measured parameter, calculating depth shifts for the primary log and performing depth matching of the primary log, based on the calculated depth shifts, to obtain a depth matched primary log, applying the same depth shifts to the second log, and generating a map of geological features of the subsurface based on the depth matched primary and secondary logs.

According to another embodiment, there is a computing device for depth matching well log data associated with a subsurface, and the computing device includes an interface configured to receive recorded well log data and a processor connected to the interface. The processor is configured to divide the recorded well log data into a primary log and a secondary log, wherein the primary log is related to a first measured parameter and the secondary log is related to a second measured parameter, which is different from the first measured parameter, calculate depth shifts for the primary log and performing depth matching of the primary log, based on the calculated depth shifts, to obtain a depth matched primary log, apply the same depth shifts to the second log, and generate a map of geological features of the subsurface based on the depth matched primary and secondary logs.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of a well drilling into a subsurface that holds a resource reservoir;

FIG. 2 is a flow chart of a method for depth matching well log data and generating a map of geological features of the subsurface of FIG. 1;

FIG. 3A schematically illustrates recorded well log data, FIG. 3B schematically illustrates a primary log, and FIGS. 3C and 3D schematically illustrate secondary logs;

FIG. 4 is a flow chart of a method for calculating an amount of a depth shift for the primary log;

FIG. 5 schematically illustrates a reference run and plural comparative runs associated with the recorded well log data for a given well;

FIG. 6 schematically illustrates overlaps between the various runs of FIG. 5;

FIG. 7 illustrates the maximizing of a correlation coefficient between a comparative run and a reference run for calculating a block shift for a comparative run;

FIG. 8 schematically illustrates the application of an affine warping method for calculating variable shifts for the comparative run;

FIGS. 9A and 9B schematically illustrate the application of the variable shift calculated in FIG. 8 to various runs;

FIG. 10 schematically illustrates a new reference run obtained from merging a previous reference run with a depth matched comparative run; and

FIG. 11 is a schematic diagram of a computing device that may implement any of the methods discussed in this document.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed with regard to a primary log (which is part of the well log for a given well) being selected to represent gamma-ray data and all other data belongs to corresponding secondary logs. However, the embodiments to be discussed next are not limited to the primary log including only the gamma-ray data, but the primary log may be selected to include any other data instead of the gamma-ray data.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a well log data depth aligning system and method receives plural log data and preprocess this data. The logs are divided into primary logs and secondary logs and depth matching is first performed on the primary logs. In one application, there is a single primary log and one or more secondary logs. The amounts of depth shifting and order of merging obtained for the primary log(s) are then applied to the secondary logs that come from a corresponding frame. Prior to discussing this method in more detail, a few technical terms are introduced. The method receives as input one or more binary files for raw well logs. These files are called digital log interchange standard (DLIS) files and they comply with a certain standard. For example, a DLIS file has a file header and metadata. The metadata may include the well name, run number, field name, producer name, company, country, start date, bit size, index type, etc. A further type of file that may be used by the method, especially for electronic transmission of the digital wireline logs, is the Log ACSII Standard (LAS) file. The LAS file standardizes the digital log curve information for personal computer users.

The disclosure also uses the term “frame,” which is a computer science term and is a data object that contains all logs acquired in a logging run. The log data may be split into primary logs and secondary logs. The primary logs may include, for example, gamma-ray logs and the secondary logs include all other data that is not in the primary logs. In one embodiment, the gamma-ray logs are selected as the primary logs because they are more accurately associated with the depth of the well than the other data. In another embodiment, the gamma-ray logs are selected as the primary logs because they exist in every toolstring run as a reference. In yet another embodiment, a different log may be selected to be the primary log and the gamma-ray log may be selected to be part of the secondary log.

The method uses the concepts of “reference run” and “comparative run” for analyzing the data in a given log data and aligning this data for depth. The reference run is considered in this document to be data of a logging run whose depth is considered to be the reference while the comparative run is data of a logging run whose depth is compared to the reference run. The method, as discussed later in more detail, fuses the reference run with one or more comparative runs (which are depth aligned) when certain conditions are met.

The method also uses the concepts of “block shift” and “variable shift.” Block shift is a distance (depth) that is calculated by the method and applied to all depth steps of the log data, i.e., all the depth samples of the log data are shifted by the same amount. The variable shift calculates different depth shifts for different depth steps. While the method uses as input DLIS files, the method generates an output dataset that includes all merged, and depth aligned logs, exported in the LAS format by default or user specified.

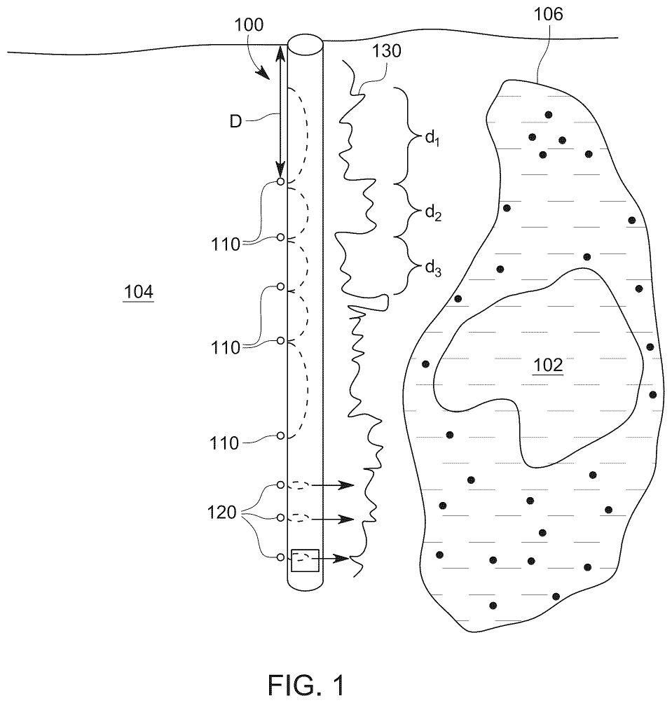

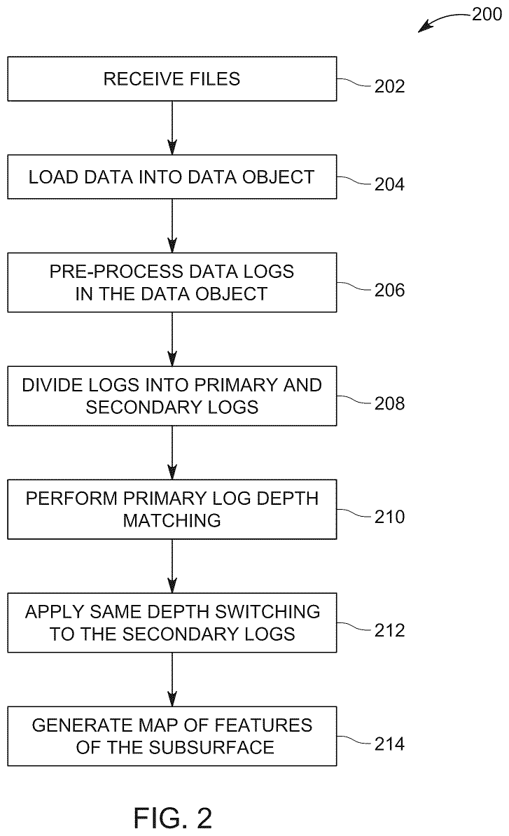

A method 200 for aligning the log data is now discussed with reference to FIG. 2. The method 200 starts by receiving in step 202 one or more DLIS format files that contain wireline and/or logging-while-drilling data of a given well (e.g., well 100 in FIG. 1). Note that the method is applied to the data of a single well for alignment. Then, the method may be applied to the data of a different well and so on. Both the wireline and/or logging-while-drilling data may include measurements that, when processed, provide information about lithology, porosity, pore geometry, permeability, water saturation, and resistivity of the subsurface around the well. The data of the DLIS format files is then processed (e.g., loaded) in step 204 into a data object, in which each row is a specific log or a log run and the log includes specific log values. The data object also includes corresponding depth steps for each log run, and other metadata.

The method may optionally pre-process in step 206 the data collected in the data object, for example, to remove flat intervals (i.e., intervals where the measured values experience no variation), resampling, and interpolating the missing data. Desired metadata (e.g., the depth of the casing point) are parsed into appropriate data types accordingly. Note that noise, spikes and other undesired elements may be present in the recorded data in the received files and there are many pre-processing procedures that may be performed on the data before aligning the depth. However, as the focus of this invention is not on the pre-process step, details about this step are omitted.

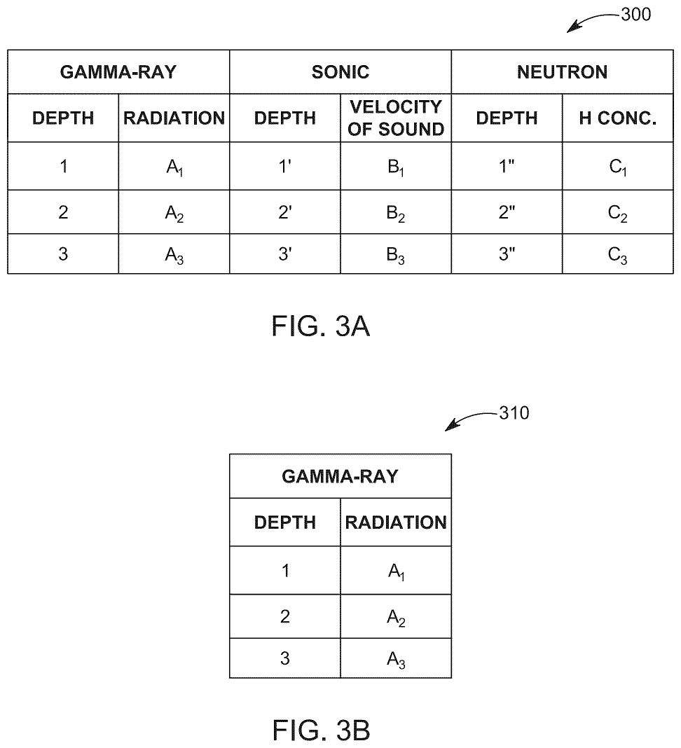

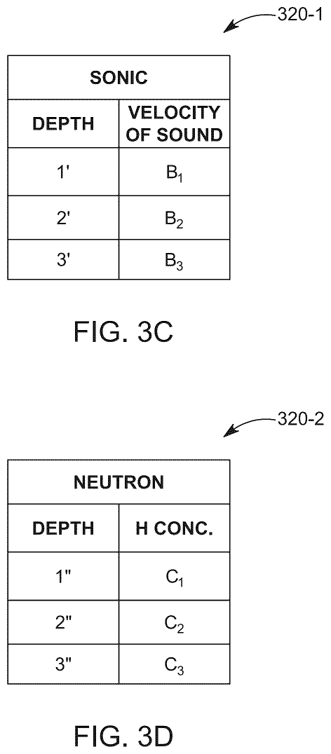

In step 208, the method divides all logs (i.e., recorded data logs) into primary logs and secondary logs. FIG. 3A schematically illustrates a log 300 that includes data associated with a given log run (e.g., described by depths 1, 2, and 3 in the figure). The data may be gamma-ray measurements A1 to A3, sonic measurements B1 to B3, and neutron measurements C1 to C3. Those skilled in the art would understand that more or less data may be part of the log 300. The figure shows only measured values for three depths. However, many more measurements for many more depths may be part of the log data. Also note that the figure suggests that the data for the gamma radiation is measured at different depths from the sonic data, i.e., the depths where the various type of data are recorded do not have to be the same. FIG. 3B shows a primary log 310, including only the gamma-ray data (extracted from the log data 300). FIGS. 3C and 3D show the secondary logs (two in this case, but more are possible) 320-1 and 320-2 extracted from the original log data 300. Note that each of the primary and secondary logs includes data related to a single measured parameter while the well log data 300 may include measurements associated with plural parameters.

In one embodiment, each separated set of log is a dictionary whose keys are log names and values are data objects containing all log runs of corresponding log names. The log name can be mnemonic or alias. In the latter case, the user needs to specify a list of mnemonics that belong to each alias. For example, if the user specifies that an alias “P_sonic” includes mnemonics “DT” and “DTC”, then the key will be “P_sonic” and the corresponding value will be data of all log runs whose names are “DT” or “DTC”.

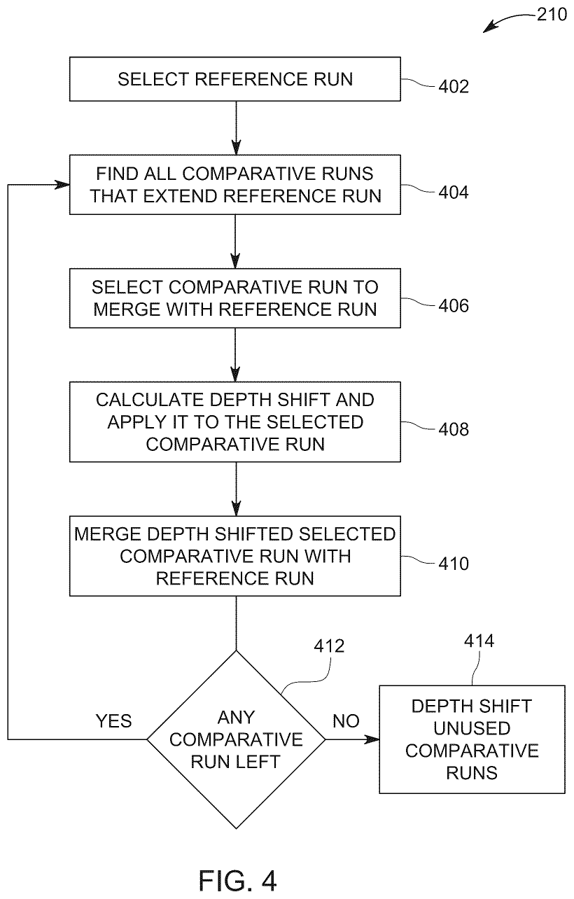

The method then proceeds to perform in step 210 depth matching for each primary log 310. This step is discussed in more detail with regard to FIG. 4. Step 210 includes a substep 402 of choosing a reference run from the primary log 310. Note that the primary log 310 may include plural runs, similar to the log run. The reference run is selected either by the user or, by default, e.g., the deepest run (with largest depth), or, optionally, the run that has the best metric based on a run maximum depth and run data quality. A data quality metric, which is a portion of data points that are not outliers, is used to evaluate the data quality of the run. A depth metric for selecting the reference run may be, in one embodiment, a ratio of the maximum depth of the run to be considered and the maximum depth of all runs. A metric used for selecting the reference run may then be a product of these two metrics (data quality metric and depth metric).

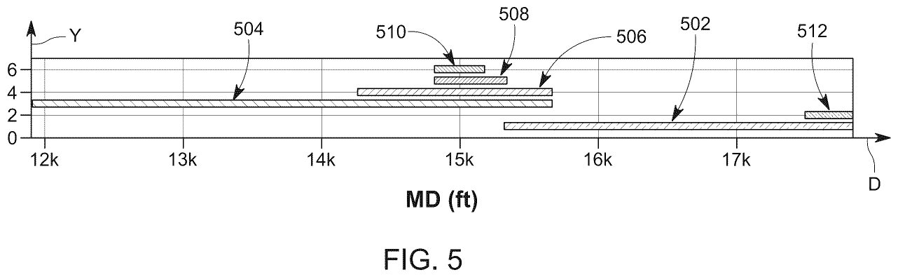

FIG. 5 schematically shows six runs 502 to 512. In this example, the reference run is 502 and all other runs are considered comparative runs. A goal of step 210 is to align these runs and merge them, if possible, into a single run. Note that FIG. 5 shows on axis D the depth (in ft) associated with the measured gamma ray radiation, and the measured value (unitless, relative value) of the gamma gay radiation is shown on the Y axis. The figure shows that the reference run 502 overlaps with comparative runs 504, 506, 508, and 512 but not with the comparative run 510.

In substep 404, the method selects all the comparative runs that can extend the (depth) coverage of the reference run. In the example of FIG. 5, comparative run 512 does not extend the coverage of the reference run 502. However, the other comparative runs extend the coverage of the reference run. Note that for a comparative run to extend the reference run it is not necessary that the reference run and comparative run has any depth portion in common.

Next, the method selects in substep 406 one comparative run (e.g., 504) to merge with the reference run 502. The selection of the comparative run in substep 406 may be based on various metrics. For example, if there are overlap intervals between the reference run 502 and a couple of the comparative runs, the comparative run that has the best (1) similarity metric (e.g., correlation), or (2) normalized correlation coefficient (by default or user-specified) is chosen. The normalized correlation coefficient (2) between two vectors x and y is calculated for a number of lags t, to be set by the user, and not exceeding the number of samples in the overlap of the two vectors, as follows:

$${R}_{x y} ( τ ) = {\sum }_{i} x [ i - τ ] y [ i ] ,$$

where the sum is over the samples i in the overlap zone. Lags are usually symmetric around the zero lag (τ=0) and with a number of samples dependent on the sample rate and the maximum expected lag, representing the maximum depth adjustment that can subsequently be applied.

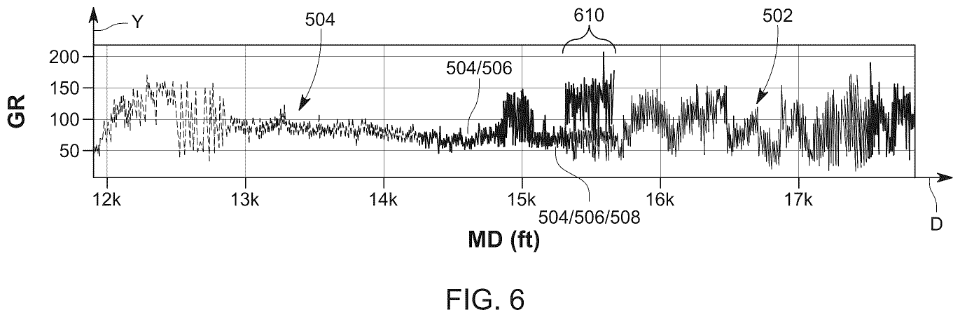

Then, the method normalizes the expression R_{xy}(t) by the product of the Euclidean norms of the vectors x and y. The Euclidean norm of a vector sums the elements squared of the vector (its samples in the overlap zone) and then takes the square root of this sum. The vector norms used in the normalization correspond to the segments of data used in the correlation R as written above. After normalization, the correlation coefficient takes on values in the range −1 to +1. The maximum of the normalized correlation coefficient is determined, and this gives the depth shift that is applied to the comparative run (the reference run remains fixed in depth). FIG. 6 shows an overlap 610 between runs 502 and 504, and the normalized correlation coefficient is calculated, as described above, only for parts of the runs 502 and 504 that belong to the overlap 610.

However, if there is no overlap interval between the reference run 502 and the comparative runs (e.g., 510), the comparative run that has the best metric based on (A) a difference between (1) the comparative run's maximum depth and (2) the reference run's minimum depth, and (B) the comparative run's data quality is chosen. The data quality metric is the same as discussed above. The depth metric for selecting a non-overlapping comparative run is a ratio of the maximum/minimum depth of the comparative run to be considered and the minimum/maximum depth of the reference run when merging upward/downward, respectively. In one embodiment, the metric for selecting non-overlapping comparative run is the product of these two metrics. Note that although the comparative run that has no overlap interval with the reference run is not merged with the reference run, the depths of this comparative run are still shifted based on optimizing a similarity metric like for the other comparative runs.

For example, as shown in FIG. 6, the comparative run 504 has been selected in substep 406 to be merged with the reference run 502 as it has the best similarity metric. FIG. 6 shows the measured gamma-ray values of the various runs on the Y axis, and also the overlap 610 of the reference run 502 and the selected comparative run 504. While other overlaps between the reference run 502 and other comparative runs are present, none of these additional overlaps have a similarity metric better than the comparative run 504.

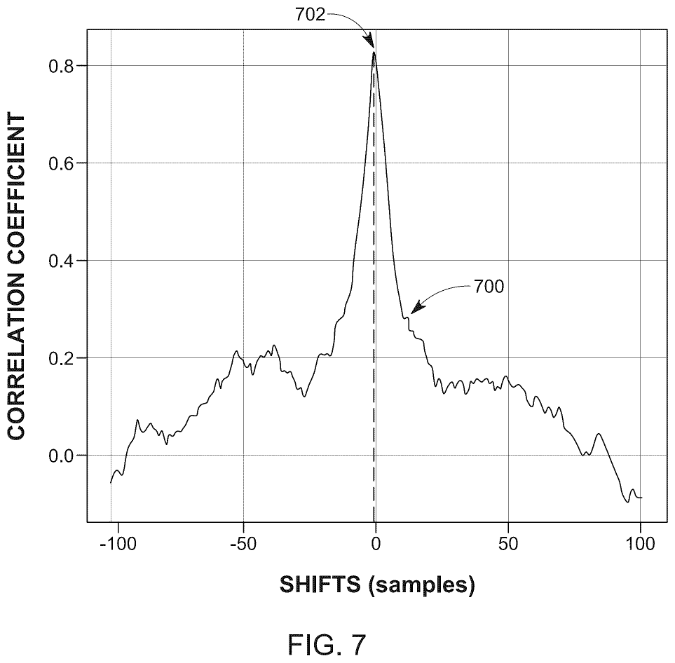

Returning to FIG. 4, in substep 408, a block depth shift is calculated for the chosen comparative run 504 and the calculated depth shift is applied to the comparative run 504, to depth match the reference run 502. If there is an overlap interval between the two runs (e.g., 502 and 504), the comparative run (504) is shifted so that the similarity metric between the comparative run and the reference run in the overlap interval is optimized. The amount of block shift (for shifting the comparative run) is calculated by finding the extremum (i.e., either the minimum or maximum) of the similarity metric against the possible shifts. For example, FIG. 7 shows the maximization of the correlation coefficient (plotted on the Y axis) versus possible block shifts (illustrated on the X axis) between the selected comparative run and the reference run. For the case illustrated in FIG. 7, a comparative run block shift 702 of 2 depth steps, in the upward direction, is found. Note that in FIG. 7, the comparative run has been shifted between −100 shifts and +100 shifts relative to the reference run, and for each shifted comparative run, a corresponding correlation coefficient has been calculated. Curve 700 in FIG. 7 corresponds to all calculated depth shifts. The maximum 702 of the curve 700 is selected to be the block shift to be applied to the comparative run. While the example shown in FIG. 7 used the maximization of the correlation coefficient between the reference and comparative runs, one skilled in the art would understand that other metrics may be used for determining a correlation between the two runs. Also note that the process illustrated in FIG. 7 provides/calculates the block shift for the comparative run.

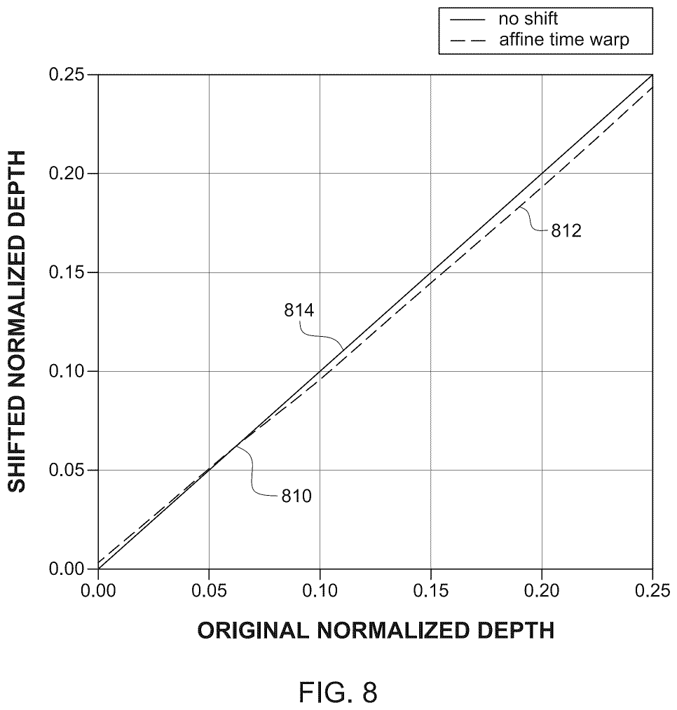

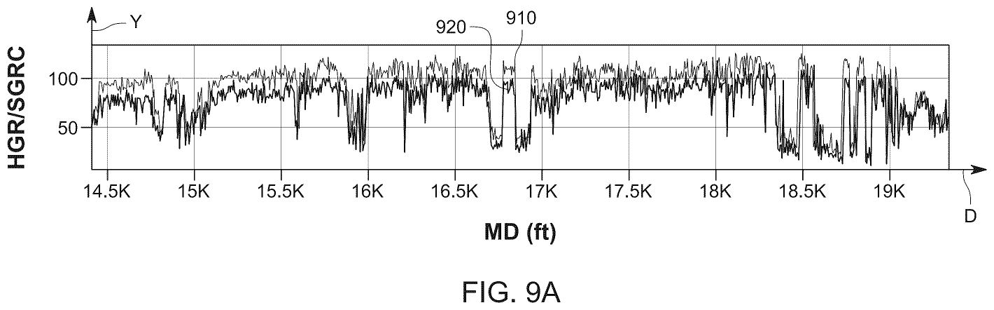

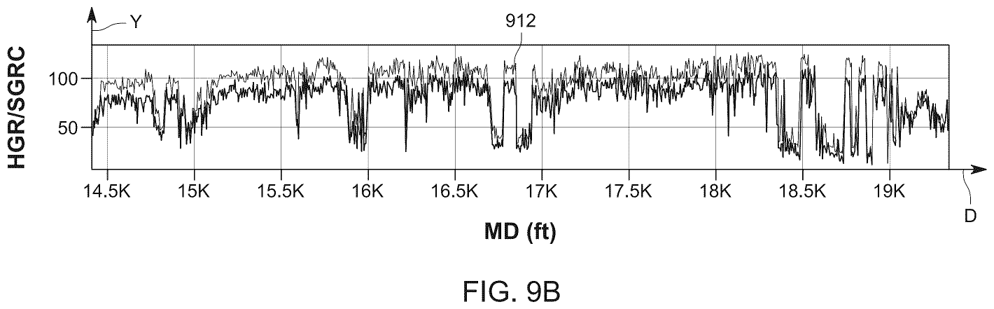

Variable shifting may also be performed, for example, with a constrained time warping algorithm. The variable shifting is (always) performed after block shifting. However, if the similarity metric after variable shifting is not better than that after block shifting alone, the variable shifting will be undone. The number of knots is identified from sequential cross validation. In affine warping, a warp path is forced to be piecewise affine. A knot is the point where the warp path changes from one affine function to another. For example, FIG. 8 shows a knot 810 being located where the warp path 812 changes its direction (around 0.06 of the original normalized depth illustrated on the X axis) relative to a no shift curve 814. The positions of knots are identified based on a local random search optimization and the warping functions between knots are forced to be affine as discussed in [6]. If there is no overlap interval, the amount of shift is zero. FIGS. 9A and 9B illustrate the effect of variable shifting using affine warping by showing two gamma runs before and after variable shifting, respectively. In this case, the shallower part and the deeper part of a smoothed gamma ray combined (SGRC) run 910 need to be shifted in opposite directions (upward and downward, respectively) to match a high-resolution gamma ray (HGR) run 920. This opposite shifting cannot be performed by block shifting. The Y direction of these figures show absolute values of the measured gamma rays.

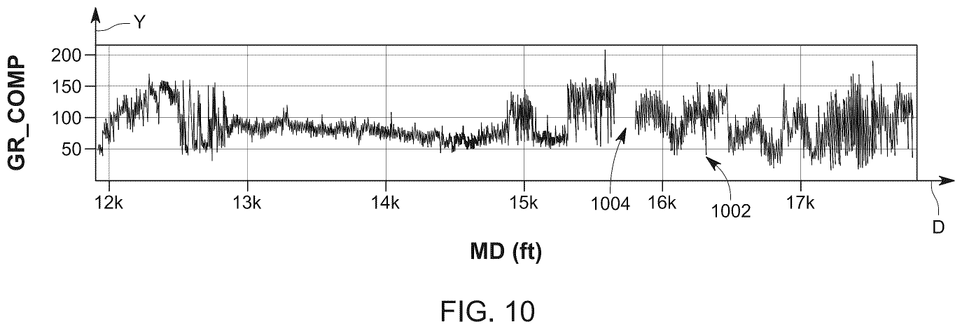

Returning to FIG. 4, the method then advances to substep 410 for merging the depth shifted selected comparative run with the reference run to form a new reference run 1002, as schematically shown in FIG. 10. During this step, for a case of upward merging (i.e., the depth shifted selected comparative run is above, in terms of height, the reference run), a casing interval 1004 is removed from the reference run and a rathole interval is removed from the comparative run before the merging. About the casing interval, in a log run, wireline logging is performed after drilling is stopped and before the casing is set. After the casing is set, the procedure of drilling, logging, and casing is carried out for the next log run. The “casing interval” is the interval at the top of a wireline log run that is affected by the casing of the previous log run. About the rathole interval, this is the interval drilled before the casing was set, but is not covered by the casing after the casing was set, i.e., this interval goes beyond the current casing depth as the casing cannot ordinarily be set to the exact bottom hole depth. Thus, any log run performed past the casing, into the rathole interval, cannot bend to reach the borehole wall and thus, the portion of the log run performed in the rathole reads the drilling mud and not the borehole wall. For this reason, the readings for the rathole are removed during the data processing. Most tools must be flush against the wall to read correctly, and this is usually not possible in the rathole interval. For the case of downward merging, the rathole is removed from reference run and the casing interval is removed from comparative run.

For substep 410, the depth of the casing point is read from the metadata or identified by comparing the reference run to the comparative run or by comparing segments of the reference run to each other. If there is still an overlap interval between the reference run 502 and the depth shifted comparative run 504, by default the shallower run supersedes the deeper run unless the user specifies otherwise. The method then estimates in substep 412 whether any comparative run is left. If the answer is YES, the method returns to substep 404 and finds all the comparative runs that now extend the new reference run 902. If the answer is NO, the method advances to substep 414, where the block shift calculated in substep 408 is also applied to all unused comparative runs.

Returning to the method of FIG. 2, after the step 210 of performing primary log depth matching between the reference run and the comparative runs, the method applies in step 212 the amounts of depth shifting (both block shift and variable shift) from the primary logs 310, to the secondary logs 320 from the corresponding frame 300. The order of merging of the secondary logs 320 is obtained independently by applying the step 210 excluding substep 408. Having aligned and merged together the various runs, it is now possible to generate in step 214 one or more geological features or formations 106 (which are presented to the user embedded in an image) of the subsurface 104 around the well 100, which is indicative of the resource 102. Note that the geological features or formations 106 may include, for example, a fault line, which is typically associated with an oil and gas reservoir. Other geological features or formations may be reproduced based on the aligned and merged runs calculated in step 212. In one application, the generated geological features or formations are presented as a subsurface map to the user. Such a map is then used by a resource exploration company to further drill a well to directly reach the resource.

Compared to the current manual shifting and merging process, the process illustrated in FIG. 2 is more systematic and produces more consistent results as it always checks all comparative runs to select the best one and performs shifting according to a consistent criterion. The two-step shifting that includes block shifting and variable shifting is more efficient, more robust, and yet more flexible than the existing automated methods. Compared to previous correlation-based methods, this method only uses correlation for block shifting, which not only reduces the search space and hence improves computer efficiency, but is also more robust as the correlation is sensitive to noises.

Compared to neural-network-based methods, this method is essentially self-supervised. Therefore, the computational expense on model hyperparameters tuning and training is much lower. Despite this, the method is flexible enough to manage variable shifting. The robustness of variable shifting is controlled by selected cross-validation methods and by constraining the warping function to be piecewise affine.

The methods discussed herein may be applied not only to the field of subsurface exploration, for example, hydrocarbon exploration and development, but also to the field of geothermal exploration and development, and carbon capture and sequestration, or other natural resource exploration and exploitation. They could also be employed for surveying and monitoring for windfarm applications, both onshore and offshore.

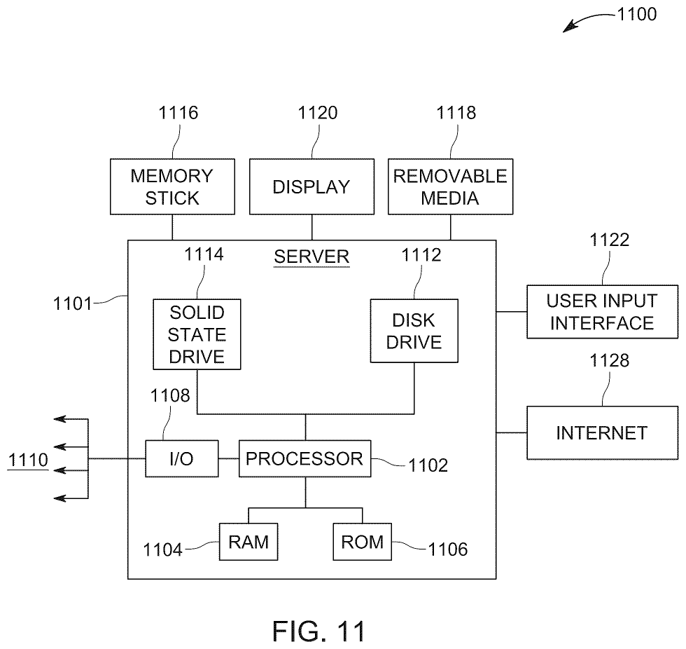

The above-discussed procedures and methods may be implemented in a computing device as illustrated in FIG. 11. Hardware, firmware, software or a combination thereof may be used to perform the various steps and operations described herein. The computing device 1100 is suitable for performing the activities described in the above embodiments and may include a server 1101. Such a server 1101 may include a central processor (CPU) 1102 coupled to a random access memory (RAM) 1104 and to a read-only memory (ROM) 1106. ROM 1106 may also be other types of storage media to store programs, such as programmable ROM (PROM), erasable PROM (EPROM), etc. Processor 1102 may communicate with other internal and external components through input/output (I/O) circuitry 1108 and bussing 1110 to provide control signals and the like. Processor 1102 carries out a variety of functions as are known in the art, as dictated by software and/or firmware instructions.

Server 1101 may also include one or more data storage devices, including hard drives 1112, solid-state drives 1114 and other hardware capable of reading and/or storing information. In one embodiment, software for carrying out the above-discussed steps may be stored and distributed on a memory stick 1116, a solid state storage device 1118 or other form of media capable of portably storing information. These storage media may be inserted into, and read by, devices such as solid state drive 1114, disk drive 1112, etc. Server 1101 may be coupled to a display 1120, which may be any type of known display or presentation screen, such as LCD, plasma display, cathode ray tube (CRT), etc. A user input interface 1122 is provided, including one or more user interface mechanisms such as a mouse, keyboard, microphone, touchpad, touch screen, voice-recognition system, etc.

Server 1101 may be coupled to other devices, such as CT scan, MRI machine, or any other data imaging systems. The server may be part of a larger network configuration as in a global area network (GAN) such as the Internet 1128, which allows ultimate connection to various landline and/or mobile computing devices.

As described above, the apparatus 1100 may be embodied by a computing device. However, in some embodiments, the apparatus may be embodied as a chip or chip set. In other words, the apparatus may comprise one or more physical packages (e.g., chips) including materials, components and/or wires on a structural assembly (e.g., a baseboard). The structural assembly may provide physical strength, conservation of size, and/or limitation of electrical interaction for component circuitry included thereon. The apparatus may therefore, in some cases, be configured to implement an embodiment of the present invention on a single chip or as a single “system on a chip.” As such, in some cases, a chip or chipset may constitute means for performing one or more operations for providing the functionalities described herein.

The processor 1102 may be embodied in a number of different ways. For example, the processor may be embodied as one or more of various hardware processing means such as a coprocessor, a microprocessor, a controller, a digital signal processor (DSP), a processing element with or without an accompanying DSP, or various other processing circuitry including integrated circuits such as, for example, an ASIC (application specific integrated circuit), an FPGA (field programmable gate array), a microcontroller unit (MCU), a hardware accelerator, a special-purpose computer chip, or the like. As such, in some embodiments, the processor may include one or more processing cores configured to perform independently. A multi-core processor may enable multiprocessing within a single physical package. Additionally or alternatively, the processor may include one or more processors configured in tandem via the bus to enable independent execution of instructions, pipelining and/or multithreading.

In an example embodiment, the processor 1102 may be configured to execute instructions stored in the memory device 1104 or otherwise accessible to the processor. Alternatively or additionally, the processor may be configured to execute hard coded functionality. As such, whether configured by hardware or software methods, or by a combination thereof, the processor may represent an entity (e.g., physically embodied in circuitry) capable of performing operations according to an embodiment of the present invention while configured accordingly. Thus, for example, when the processor is embodied as an ASIC, FPGA or the like, the processor may be specifically configured hardware for conducting the operations described herein. Alternatively, as another example, when the processor is embodied as an executor of software instructions, the instructions may specifically configure the processor to perform the algorithms and/or operations described herein when the instructions are executed. However, in some cases, the processor may be a processor of a specific device (e.g., a pass-through display or a mobile terminal) configured to employ an embodiment of the present invention by further configuration of the processor by instructions for performing the algorithms and/or operations described herein. The processor may include, among other things, a clock, an arithmetic logic unit (ALU) and logic gates configured to support operation of the processor.

The term “about” is used in this application to mean a variation of up to 20% of the parameter characterized by this term.

It will be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

The disclosed embodiments provide a method and system for depth shifting one or more comparative runs and merging them with a reference run. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] Zangwill, J. (1982), Depth matching-a computerized approach. SPWLA Annual Logging Symposium, SPWLA-1982.
[2] Kerzner, M. G. (1984), A solution to the problem of automatic depth matching. SPWLA Annual Logging Symposium, SPWLA-1984.
[3] Zimmermann, T., Liang, L., and Zeroug, S. (2018), Machine-learning-based automatic well-log depth matching. Petrophysics, 59 (06), 863-872.
[4] Torres Caceres, V. A., Duffaut, K., Yazidi, A., Westad, F., & Johansen, Y. B. (2022a), Automated well log depth matching: Late fusion multimodal deep learning. Geophysical Prospecting.
[5] Torres Caceres, V. A., Duffaut, K., Yazidi, A., Westad, F. O., & Johansen, Y. B. (2022b), Automated well-log depth matching-1d convolutional neural networks vs. classic cross correlation. Petrophysics, 63 (01), 12-34.
[6] williams, A. H., Poole, B., Maheswaranathan, N., Dhawale, A. K., Fisher, T., Wilson, C. D., Brann, D. H., Trautmann, E. M., Ryu, S., Shusterman, R., & others. (2020). Discovering precise temporal patterns in large-scale neural recordings through robust and interpretable time warping. Neuron, 105 (2), 246-259.

What is claimed is:

1. A method for depth matching well log data associated with a subsurface, the method comprising:
receiving recorded well log data;
dividing the recorded well log data into a primary log and a secondary log, wherein the primary log is related to a first measured parameter and the secondary log is related to a second measured parameter, which is different from the first measured parameter;
calculating depth shifts for the primary log and performing depth matching of the primary log, based on the calculated depth shifts, to obtain a depth matched primary log;
applying the same depth shifts to the second log; and
generating a map of geological features of the subsurface based on the depth matched primary and secondary logs.

2. The method of claim 1, wherein the first measured parameter is gamma ray radiation.

3. The method of claim 1, wherein the step of calculating comprises:
selecting a reference run from the primary log; and
selecting a comparative run from plural comparative runs based on a condition, wherein the comparative run extends the reference run in terms of depth coverage.

4. The method of claim 3, wherein, when the selected comparative run overlaps with the reference run, the condition is one of:
a similarity metric, or
a normalized correlation coefficient.

5. The method of claim 3, wherein, when the selected comparative run does not overlap with the reference run, the condition is a metric that is based on (A) a difference between (1) a maximum depth of the comparative run, and (2) a minimum depth of the reference depth, and (B) a data quality metric of the comparative run.

6. The method of claim 3, wherein the step of calculating further comprises:
depth shifting the selected comparative run relative to the reference run, when there is an overlap interval between the selective comparative run and the reference run, until a similarity metric between the selective comparative run and the reference run reaches a maximum or a minimum;
selecting a depth shift that corresponds to the maximum or minimum of the similarity metric; and
applying the depth shift to all depths of the selected comparative run to obtain a depth shifted comparative run.

7. The method of claim 6, wherein the step of calculating further comprises:
performing variable shifting based on a constrained time warping method, wherein the variable shifting is calculated for part of the depths of the comparative run.

8. The method of claim 6, wherein the step of calculating further comprises:
merging the depth shifted comparative run with the reference run to generate a new reference run.

9. The method of claim 8, further comprising:
selecting another comparative run of the plural comparative runs; and
repeating the steps of depth shifting, selecting, applying, and merging for the another comparative run relative to the new reference run.

10. The method of claim 8, wherein the step of merging comprises:
for upward merging, removing a casing interval from the reference run and removing a rathole interval from the comparative run; and
for downward merging, removing the rathole interval from the reference run and removing the casing interval from the comparative run.

11. A computing device for depth matching well log data associated with a subsurface, the computing device comprising:
an interface configured to receive recorded well log data; and
a processor connected to the interface and configured to,
divide the recorded well log data into a primary log and a secondary log, wherein the primary log is related to a first measured parameter and the secondary log is related to a second measured parameter, which is different from the first measured parameter;
calculate depth shifts for the primary log and performing depth matching of the primary log, based on the calculated depth shifts, to obtain a depth matched primary log;
apply the same depth shifts to the second log; and
generate a map of geological features of the subsurface based on the depth matched primary and secondary logs.

12. The computing device of claim 11, wherein the first measured parameter is gamma ray radiation.

13. The computing device of claim 11, wherein the processor is further configured to:
select a reference run from the primary log; and
select a comparative run from plural comparative runs based on a condition, wherein the comparative run extends the reference run in terms of depth coverage.

14. The computing device of claim 13, wherein, when the selected comparative run overlaps with the reference run, the condition is one of:
a similarity metric, or
a normalized correlation coefficient.

15. The computing device of claim 13, wherein, when the selected comparative run does not overlap with the reference run, the condition is a metric that is based on (A) a difference between (1) a maximum depth of the comparative run, and (2) a minimum depth of the reference depth, and (B) a data quality metric of the comparative run.

16. The computing device of claim 13, wherein the processor is further configured to:
depth shift the selected comparative run relative to the reference run, when there is an overlap interval between the selective comparative run and the reference run, until a similarity metric between the selective comparative run and the reference run reaches a maximum or a minimum;
select a depth shift that corresponds to the maximum or minimum of the similarity metric; and
apply the depth shift to all depths of the selected comparative run to obtain a depth shifted comparative run.

17. The computing device of claim 16, wherein the processor is further configured to:
perform variable shifting based on a constrained time warping method, wherein the variable shifting is calculated for part of the depths of the comparative run.

18. The computing device of claim 16, wherein the processor is further configured to:
merge the depth shifted comparative run with the reference run to generate a new reference run.

19. The computing device of claim 18, wherein the processor is further configured to:
select another comparative run of the plural comparative runs; and
repeat the steps of depth shifting, selecting, applying, and merging for the another comparative run relative to the new reference run.

20. The computing device of claim 18, wherein processor is further configured to:
for upward merging, remove a casing interval from the reference run and removing a rathole interval from the comparative run; and
for downward merging, remove the rathole interval from the reference run and removing the casing interval from the comparative run.
